(19) United States
(12) Patent Application Publication
(10) Pub. No.: US 2025/0267796 A1
(43) Pub. Date: Aug. 21, 2025

(54) PRINTED BOARD MANUFACTURING METHOD AND PRINTED BOARD

(71) Applicant: CANON KABUSHIKI KAISHA, Tokyo (JP)

(72) Inventors: TSUYOSHI YAMAGUCHI, Chiba (JP); MASAMICHI IIDA, Kanagawa (JP)

(21) Appl. No.: 19/051,411

(22) Filed: Feb. 12, 2025

(30) Foreign Application Priority Data
Feb. 21, 2024 (JP) 2024-024230

(51) Int. Cl. H05K 3/00; H05K 1/18

(52) U.S. Cl. CPC H05K 3/0052; H05K 1/181; H05K 2203/0228

(57) ABSTRACT

A printed board manufacturing method for manufacturing a plurality of printed boards by cutting connecting portions of a collective printed board in which the plurality of printed boards are connected by the connecting portions. The collective printed board includes first, second and third printed boards, a first connecting portion connecting the first and second printed boards, and a second connecting portion connecting the first and third printed board. A length of the first connecting portion in a direction where the first and second printed boards are connected is longer than a length of the second connecting portion in a direction where the first and third printed boards are connected. The first, second and the third printed boards are manufactured from the collective printed board by the first connecting portion being cut with the second connecting portion.

### FIELD OF THE INVENTION AND RELATED ART

The present invention relates to a printed board manufacturing method and a printed board and, for example, to a method for manufacturing a plurality of the printed boards from a collective printed board-to-be-divided and the printed board.

In order to reduce manufacturing cost, mounting cost and administrative cost of a board, there is a case in which a configuration of mixed multi-surface mounting, in which a plurality of printed boards are manufactured from one sheet of a collective printed board-to-be-divided, is employed. Each board is connected to each other by a connecting portion of perforation having a common length of 1.0 mm, and upon dividing the printed board, a method of simultaneously dividing the connecting portions by a board dividing device has been proposed. For example, as a suitable method for dividing an atypical printed board having a complex shape, the following method is known. That is, a method in which an upper blade and a lower blade of the dividing device are lifted and lowered by an air cylinder, a hydraulic cylinder, etc., which is connected to a power source, and cut along the perforation provided to the printed board (see, for example, Japanese Patent Application Laid-Open No. H02-124296, Japanese Patent Application Laid-Open No. H07-066509 and Japanese Patent Application Laid-Open No. H08-141998).

### SUMMARY OF THE INVENTION

FIG. 13 is a view illustrating a configuration of a board dividing device 100. In the board dividing device 100 in FIG. 13, upon lowering a lifting and lowering plate 4, leading edges of blades of an upper dividing blade 8 and a lower dividing blade 7 come into slide contact with a perforation 5 of a collective printed board-to-be-divided 9 from above and below, and, by the perforation being cut, the collective printed board-to-be-divided 9 is divided into each of the printed boards.

However, specification of a board size and a shape of each printed board is fixed, and upon attempting to connect each board with connecting portions having the same length, the following problem arises. That is, a problem that there is a case to have an arrangement such that a length between the boards is longer than a length of the connecting portion, and between the boards in this manner, the connecting portion cannot be provided to connect the boards, and a strength of the collective printed board-to-be-divided is reduced. In a case in which components are mounted on the collective printed board-to-be-divided, after the components are mounted in a state of a bare board, in which the boards are connected to each other by the connecting portions, the collective printed board-to-be-divided is divided by the board dividing device. If a strength of the collective printed board-to-be-divided is low, a problem that the bare board is cracked before components are mounted and a mounter cannot mount the components in predetermined positions also arises.

The present invention is conceived under circumstances as described above, and an object of the present invention is to keep a strength of a collective printed board.

An aspect of the present invention is as following.

(1) A printed board manufacturing method for manufacturing a plurality of printed boards by cutting connecting portions of a collective printed board in which the plurality of printed boards are connected by the connecting portions and are disposed, wherein the collective printed board comprising: a first printed board; a second printed board; a third printed board; a first connecting portion connecting the first printed board and the second printed board; and a second connecting portion connecting the first printed board and the third printed board, wherein a length of the first connecting portion in a direction where the first printed board and the second printed board are connected is longer than a length of the second connecting portion in a direction where the first printed board and the third printed board are connected, and wherein first printed board, the second printed board and the third printed board are manufactured from the collective printed board by the first connecting portion being cut with the second connecting portion.

An aspect of the present invention is as following.

(2) A printed board manufacturing method for manufacturing a plurality of printed boards by cutting a connecting portion of a collective printed board in which the plurality of printed boards are connected by the connecting portion and are disposed, wherein the collective printed board comprising: a first printed board; a second printed board; and a connecting portion connecting the first printed board and the second printed board, wherein the first printed board or the second printed board includes a component mounted on an end portion to which the connecting portion is connected, wherein the connecting portion is divided by a dividing device, wherein in a state in which the collecting printed board is mounted on the dividing device, the dividing device includes a lower dividing blade provided below the collective printed board in a vertical direction and a upper dividing blade provided above the collective printed board so as to be paired with the lower dividing blade, wherein the upper dividing blade includes a first vertical surface parallel to the vertical direction, a first inclined surface inclined to the vertical direction and a first leading edge portion formed of a crossing line between the first vertical surface and the first inclined surface, wherein the lower dividing blade includes a second vertical surface parallel to the vertical direction, a second inclined surface inclined to the vertical direction and a second leading edge portion formed of a crossing line between the second vertical surface and the second inclined surface, wherein the collective printed board is mounted on the dividing device so that the connecting portion is positioned above the lower dividing blade, wherein in a case in which the component is mounted on an upper surface of the first printed board or the second printed board, the first vertical surface of the upper dividing blade is disposed to as to be opposed to the component, wherein in a case in which the component is mounted on a lower surface of the first printed board or the second printed board, the second vertical surface of the lower dividing blade is disposed to as to be opposed to the component, and wherein the upper dividing blade contacts the connecting portion from above the connecting portion, comes into slide contact with the lower dividing blade through the connecting portion and cuts the connecting portion, and thereby the first printed board and the second printed board are manufactured from the collective printed board.

An aspect of the present invention is as following.

(3) A printed board on which a component is to be mounted, the printed board comprising: a first projected portion and a second projected portion projected from an outer end portion of the printed board, wherein a length of the first projected portion in a direction where the first projected portion is projected is longer than a length of the second projected portion in a direction where the second projected portion is projected.

Further features of the present invention will become apparent from the following description of exemplary embodiments with reference to the attached drawings.

### BRIEF DESCRIPTION OF THE DRAWINGS

FIG. 1 is an outer shape view of a conventional collective printed board-to-be-divided for comparing with an Embodiment 1.

FIG. 2 is an outer shape view of a collective printed board-to-be-divided in the Embodiment 1.

FIG. 3 is an enlarged perspective dimensional view of the collective printed board-to-be-divided and upper and lower dividing blades in the Embodiment 1.

FIG. 4 is an outer shape view of printed boards after the collective printed board-to-be-divided is divided in the Embodiment 1.

FIG. 5 is an outer shape view of a conventional collective printed-to-be-divided for comparing with an Embodiment 2.

FIG. 6, part (a) and part (b), includes an enlarged perspective dimensional view of the conventional collective printed board-to-be-divide and an upper dividing blade for comparing with the Embodiment 2, and an A-A cross-sectional view in FIG. 5.

FIG. 7 is an outer shape view of a collective printed board-to-be-divided in the Embodiment 2.

FIG. 8, part (a) and part (b), includes an enlarged perspective dimensional view of the collective printed board-to-be-divided and an upper dividing blade in the Embodiment 2, and a B-B cross-sectional view in FIG. 7.

FIG. 9 is an outer shape view of a printed board after the collective printed board-to-be-divided is divided in the Embodiment 2.

FIG. 10 is an outer shape view of a collective printed board-to-be-divided in an Embodiment 3.

FIG. 11, part (a) and part (b), includes an enlarged perspective dimensional view of the collective printed board-to-be-divided and an upper dividing blade in the Embodiment 3, and a C-C cross-sectional view in FIG. 10.

FIG. 12, part (a) and part (b), includes a D-D cross-sectional view in FIG. 10, and an outer shape view of the printed board after the collective printed board-to-be-divided is divided in the Embodiment 3.

FIG. 13 is a schematic view of a conventional example of a board dividing device.

### DESCRIPTION OF THE EMBODIMENTS

Specific configurations of the present invention to solve the above problems will be described based on the Embodiments. Incidentally, the Embodiments described below are only examples, and are not what intend to limit a technical scope of the present invention only thereto.

### General Board Dividing Device

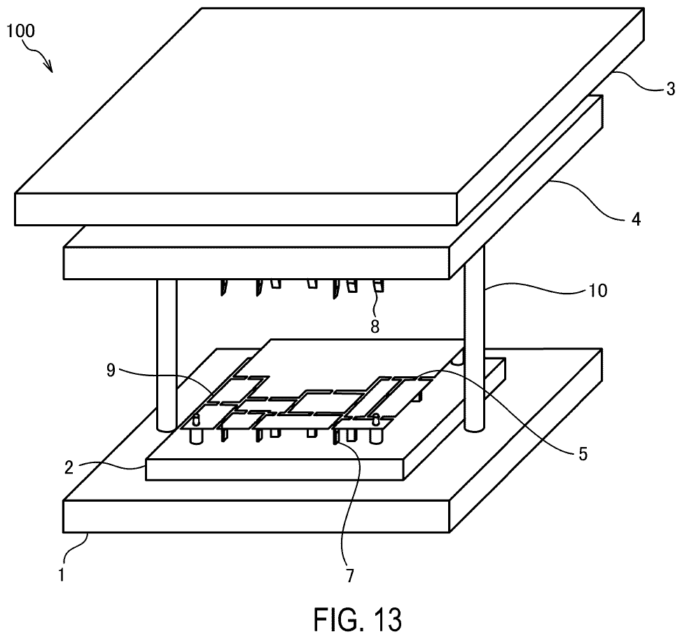

FIG. 13 is a view illustrating a configuration of a general board dividing device 100 (dividing device). The board dividing device 100 includes, in a vertical direction, a lower dividing blade, which is provided below a collective printed board, and an upper dividing blade, which is provided above the collective printed board so as to be paired with the lower dividing blade. On a board positioning table 2, a collective printed board-to-be-divided 9, on which a plurality of components are mounted, is mounted. In the collective printed board-to-be-divided 9, a plurality of perforations 5 are formed, and in order to let bonding portions of the perforations be dividing positions, in the board positioning table 2, a plurality of lower dividing blades 7 are disposed. On a base 1, pillar 10 are erected, and onto upper ends of the pillars 10, an upper plate 3 is fixed. Below the upper plate 3, a lifting and lowering plate 4 is suspended freely for lifting and lowering. To a lower surface of the lifting and lowering plate 4, a plurality of upper dividing blades 8 are fixed, and positions of the upper dividing blades 8 are arranged so as to let the bonding portions of the perforations, which are provided on the collective printed board-to-be-divided 9, be the dividing positions. Therefore, upon lowering the lifting and lowering plate 4, leading edges of the blades of the upper dividing blade 8 and the lower dividing blade 7 come into slide contact with the perforation 5 of the collective printed board-to-be-divided 9 from above and below, and by the perforations being divided, the collective printed board-to-be-divided 9 is divided into each of the printed boards. Incidentally, in the following description, it is assumed that the other configurations of the board dividing device for dividing the collective printed board except the configurations for the upper dividing blade and the lower dividing blade are the same as those in FIG. 13.

In a collective printed board, which has a configuration of general mixed multi-surface mounting, specification of a board size and a shape of each printed board is fixed. Upon arranging the printed boards, of which the shape and the specification are fixed, as many as possible on a single collective printed board, there is a case in which distances between the printed boards are not constant. On the other hand, in a case in which the printed boards are connected to each other by connecting portions at a plurality of points, that is, the printed boards have a so-called perforation configuration, a plurality of connecting portions in general are configured to have the same length. Then, upon attempting to connect the plurality of printed boards with the connecting portions having the common same length, if the connecting portions have the common same length, a part of the plurality of printed boards cannot be connected by the connecting portion. Specifically, to a point at which a distance between the printed boards is more than a length of the connecting portion, the connecting portion cannot be provided. As a result, a strength of the collective printed board may be reduced.

### EMBODIMENT 1

### General Collective Printed Board-to-be-Divided

In printed boards, there are some printed boards which are manufactured by a single board (hereinafter, referred also to as a collective printed board), in which a plurality of printed boards are arranged (collected), being divided (cut) into a plurality of the printed boards by a board dividing device (or with an equipment such as a cutter, etc. by hand). Each of the printed boards which are disposed in the collective printed board is separated into areas by slits, elongated holes, etc. (hereinafter, also referred to as perforations), and by the printed boards being connected to each other by connecting portions, a single collective printed board is constituted. An upper dividing blade and a lower dividing blade of the board dividing device cut the connecting portions which are connecting the printed boards.

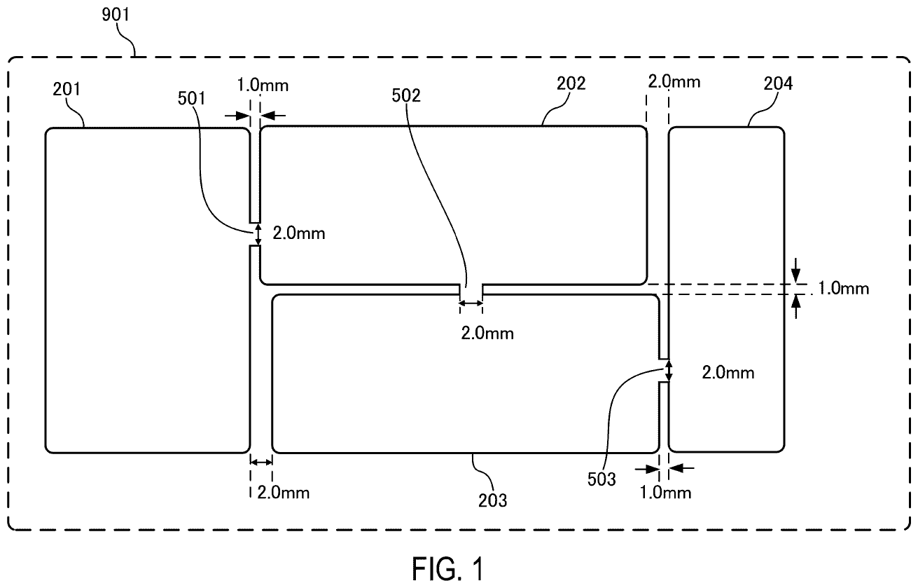

FIG. 1 is a view illustrating a configuration of an example of the collective printed board-to-be-divided as one sheet of a general collective printed board, in which a plurality of the printed boards are connected by the connecting portions having the same length of 1.0 mm and the same width of 2.0 mm. Incidentally, the length of the connecting portion refers to a length in a direction in which the printed board and the printed board are connected, and the width refers to a length in a direction perpendicular to the length. Four sheets of printed boards 201, 202, 203 and 204 are connected to each other at connecting portions 501, 502 and 503, and a collective printed board-to-be-divided 901 is constituted.

Distances of outer end portions between the printed board 201 and the printed board 202, between the printed board 202 and the printed board 203, and between the printed board 203 and the printed board 204 are 1.0 mm. Distances between the printed board 201 and the printed board 203, and between the printed board 202 and the printed board 204 are 2.0 mm. A length of the general connecting portion is 1.0 mm and a common length. Since a shape of each printed board is fixed, gaps between the printed board 201 and the printed board 203 and between the printed board 202 and the printed board 204 cannot be connected with the general connecting portion having the common length. Therefore, connecting strength between the printed boards is weak, and there is a risk that the collective printed board-to-be-divided 901 may be cracked unintentionally.

In a case in which components are mounted on the collective printed board-to-be-divided, after the components are mounted in a state of a bare board, which is connected to each other by the connecting portions (a state before being divided), the collective printed board-to-be-divided is divided by the board dividing device. That is, the board dividing device performs dividing of the perforations in a state in which a plurality of the components are mounted on the collective printed board-to-be-divided. Therefore, after the components are mounted as well, in a case in which a part of the collective printed board-to-be-divided is cracked, upon mounting the collective printed board-to-be-divided on the board dividing device, a problem that positioning thereof cannot be done also arises. Incidentally, it is assumed that the positioning of the collective printed board-to-be-divided and the board dividing device is done through a general method, for example, such as by fitting a pilot pin, which is provided to the board dividing device, into a through hole, which is provided to the collective printed board-to-be-divided.

As reasons why the length of the connecting portion is common to 1.0 mm, the following reasons can be listed. First, in a case in which a flow soldering of the components on the printed board is performed, the smaller a gap between the printed boards, the less risk of jetting up from a flow soldering layer. Therefore, as one of the reasons, in order for the gap to be as small as possible, the length of the connecting portion is set to 1.0 mm. Incidentally, if there is no jetting up, it does not matter even if the gap between the printed boards is large. In addition, for another reason, in a case in which the connecting portions are divided by hand, because it is impossible to control which positions of the connecting portions will be divided. In the case in which the connecting portions are divided by hand, upon being connected by the connecting portions having the length of 1.0 mm, after dividing, there could also be a case in which the entire connecting portion with the length of 1.0 mm remains in the printed board as a remaining of the connecting portion (also referred to as a perforation remaining.). For these reasons, in order to make the length of the connecting portion as short as possible, the length of 1.0 mm is standardized. However, in a case of dividing not by hand but by the board dividing device, since the connecting portions are divided by a leading edge of a sharp blade and can be cut stably by the leading end of the blade, it becomes possible to control a length of the perforation remaining.

### A Plurality of the Printed Boards in an Embodiment 1

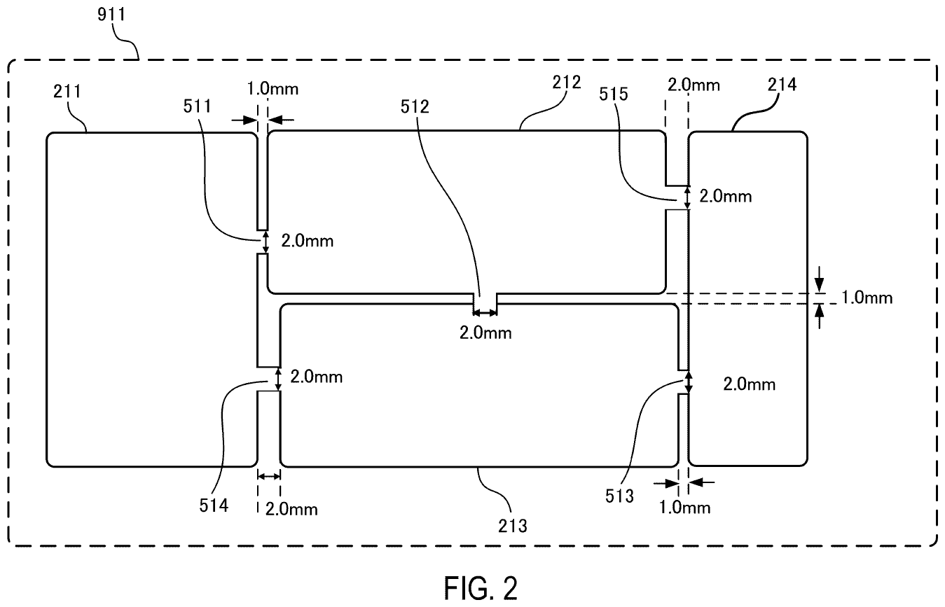

FIG. 2 is a view illustrating a configuration of a collective printed board-to-be-divided 911 as a collective printed board in an Embodiment 1. Four sheets of printed boards 211, 212, 213 and 214 are connected to each other by connecting portions 511, 512, 513, 514 and 515, and the collective printed board-to-be-divided 911 is constituted.

A distance between the printed board 211 and the printed board 212, that is, a distance between outer end portions is 1.0 mm. A distance between the printed board 212 and the printed board 213 and between the printed board 213 and the printed board 214, that is, distances between the outer end portions are 1.0 mm. A distance between the printed board 211 and the printed board 213 and between the printed board 212 and the printed board 214, that is, distances between the outer end portions are 2.0 mm. A shape of each printed board is fixed, and lengths of the connecting portions 511, 512 and 513 are 1.0 mm, and lengths of the connecting portions 514 and 515 are 2.0 mm. The collective printed board-to-be-divided 911 is constituted by the plurality of the printed boards connected by the connecting portions 511 through 513 and 514 and 515 of different lengths. By this, the connecting strength of the collective printed board-to-be-divided 911 becomes stronger compared to that of the conventional collective printed board-to-be-divided 901. Specifically, in the Embodiment 1, since the printed boards are connected by the connecting portions 514 and 515, the connecting strength is improved compared to the collective printed board-to-be-divided 901 shown in FIG. 1. Incidentally, only four printed boards 211 through 214 are illustrated in the collective printed board-to-be-divided 911, however, actually, as described in FIG. 2, a lot of the printed boards, in which some are connected to each other with the gap of 1 mm and the others are connected to each other with the gap of 2 mm, are included.

Incidentally, when the printed board 211 is defined as a first printed board, then the printed board 213 corresponds to a second printed board, and the printed board 212 corresponds to a third printed board. And then, the connecting portion 514 corresponds to a first connecting portion, and the connecting portion 511 corresponds to a second connecting portion. In addition, when the printed board 214 is defined as the first printed board, the printed board 212 corresponds to the second printed board, and the printed board 213 corresponds to the third printed board. And then, the connecting portion 515 corresponds to the first connecting portion and the connecting portion 513 corresponds to the second connecting portion.

### Contacting Manner of the Dividing Blade

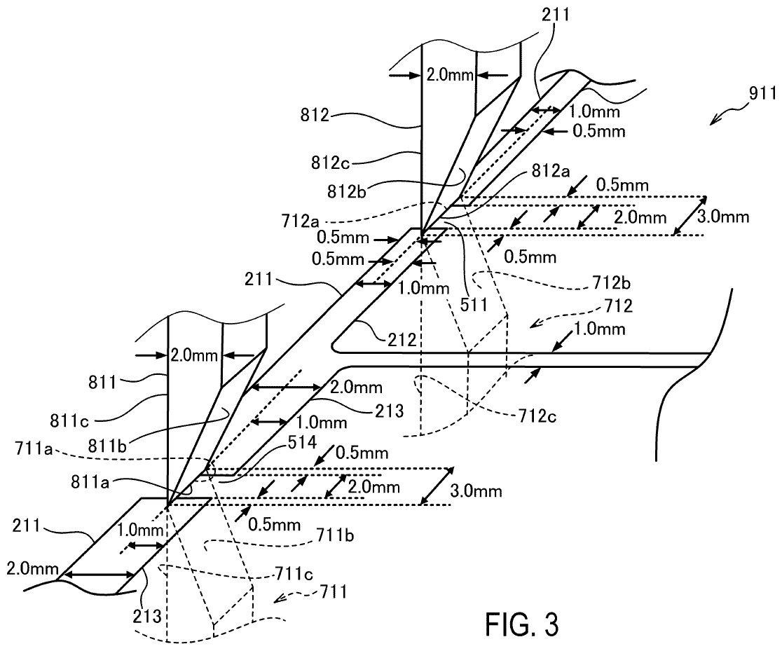

In FIG. 3, a dimensional view in a case in which the collective printed board-to-be-divided 911 is divided by the board dividing device 100, upon an upper dividing blade 811 as a first upper dividing blade contacting the connecting portion 514 and an upper dividing blade 812 as a second upper dividing blade contacting the connecting portion 511, is illustrated. A leading edge 811a as a first leading edge portion of the upper dividing blade 811 is formed by a crossing line between an inclined surface 811b as a first inclined surface with respect to a vertical direction and a vertical surface 811c as a first vertical surface parallel to the vertical direction. A leading edge 812a as a third leading edge portion of the upper dividing blade 812 is formed by a crossing line between an inclined surface 812b as a third inclined surface with respect to the vertical direction and a vertical surface 812c as a third vertical surface parallel to the vertical direction. Blade widths of each of the upper dividing blades 811 and 812 are 3.0 mm, and thicknesses thereof are 2.0 mm.

Incidentally, the board dividing device 100 is provided with a lower dividing blade 711 as a first lower dividing blade which is paired with the upper dividing blade 811, and a lower dividing blade 712 as a second lower dividing blade which is paired with the upper dividing blade 812. The lower dividing blade 711 includes a vertical surface 711c as a second vertical surface, which is parallel to the vertical direction, an inclined surface 711b as a second inclined surface, which is inclined to the vertical direction, and a leading edge 711a as a second leading edge portion, which is formed by a crossing line between the vertical surface 711c and the inclined surface 711b. The lower dividing blade 712 includes a vertical surface 712c as a fourth vertical surface, which is parallel to the vertical direction, an inclined surface 712b as a fourth inclined surface, which is inclined to the vertical direction, and a leading edge 712a as a fourth leading edge portion, which is formed by a crossing line between the vertical surface 712c and the inclined surface 712b. The collective printed board-to-be-divided 911 is mounted on the board dividing device 100 so that the connecting portion 514 is positioned above the lower dividing blade 711 and the connecting portion 511 is positioned above the lower dividing blade 712. The upper dividing blade 811 contacts the connecting portion 514 from above the connecting portion 514, comes into slide contact with the lower dividing blade 711 through the connecting portion 514, and cuts the connecting portion 514. The upper dividing blade 812 contacts the connecting portion 511 from above the connecting portion 511, comes into slide contact with the lower dividing blade 712 through the connecting portion 511, and cuts the connecting portion 511.

Upon dividing the collective printed board-to-be-divided 911, a position of the leading edge 811a of the blade of the upper dividing blade 811 is, with respect to the connecting portion 514, a position, which is 1.0 mm away from an outer end side portion of the printed board 211, and is a position, which is 1.0 mm away from an outer end side portion of the printed board 213. Furthermore, the leading edge 811a is positioned, with respect to the width 2.0 mm of the connecting portion 514, so that a center of the leading edge 811a of the blade width of 3.0 mm overlaps a center of the width of the connecting portion 514, and the blade contacts a center of the connecting portion length of 2.0 mm. The upper dividing blade 811 and the lower dividing blade 711, in a length direction of the connecting portion 514, cut the center of the connecting portion 514. In this manner, the connecting portion 514 is sandwiched between the upper dividing blade 811 and the lower dividing blade 711 and cut.

Similarly, upon dividing the collective printed board-to-be-divided printed 911, a position of the leading edge 812a of the blade of the upper dividing blade 812 is, with respect to the connecting portion 511, a position, which is 0.5 mm away from the outer end side portion of the printed board 211, and is a position, which is 0.5 mm away from an outer end side portion of the printed board 212. Furthermore, the leading edge 812a is positioned, with respect to the width 2.0 mm of the connecting portion 511, so that a center of the leading edge 812a of the blade width of 3.0 mm overlaps a center of the width of the connecting portion 511, and the blade contacts a center of the connecting portion length of 1.0 mm. The upper dividing blade 812 and the lower dividing blade 712, in a length direction of the connecting portion 511, cut the center of the connecting portion 511. In this manner, the connecting portion 511 is sandwiched between the upper dividing blade 812 and the lower dividing blade 712 and cut.

In cases of the connecting portions 512, 513 and 515 as well, similarly, corresponding upper and lower dividing blades contact centers of the connecting portion lengths, and at centers of the connecting portion lengths, the connection portions are cut. Incidentally, upon dividing the collective printed board-to-be-divided 911, mounted components on each printed board, which are not shown in the figure, are mounted on the printed board with a clearance of 1.0 mm or more to the upper and lower dividing blades so as not to hit each other.

### Connecting Portion after Being Divided

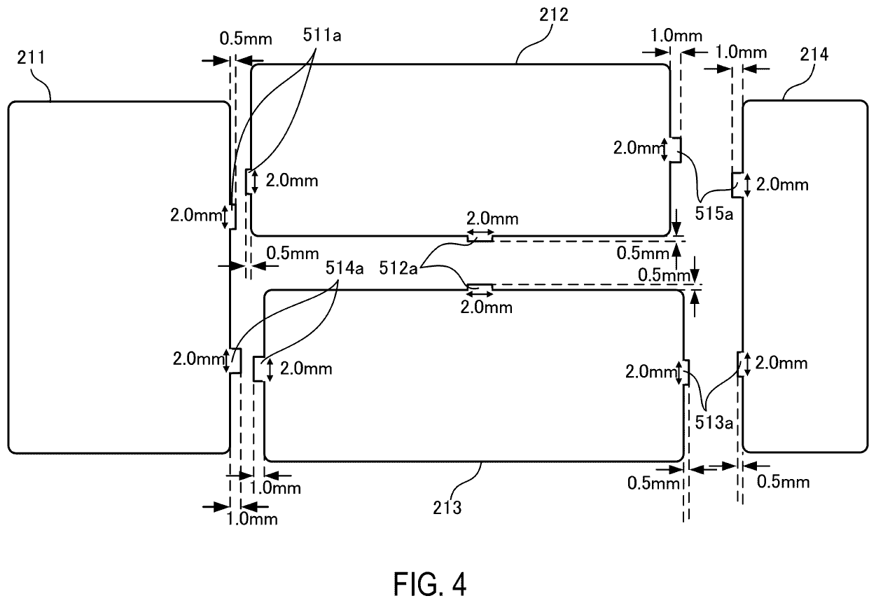

FIG. 4 is a view illustrating the plurality of printed boards after being divided. The printed board 211 after being divided includes a connecting portion remaining 514a as a first projected portion and a connecting portion remaining 511a as a second projected portion, which are projecting from the outer end portion of the printed board 211. The printed board 212 after being divided includes a connecting portion remaining 515a as the first projected portion and connecting portion remainings 511a and 512a as the second projected portions, which are projecting from the outer end portions of the printed board 212. The printed board 213 after being divided includes a connecting portion remaining 514a as the first projected portion and connecting portion remainings 512a and 513a as the second projected portions, which are projecting from the outer end portions of the printed board 213. The printed board 214 after being divided includes a connecting portion remaining 515a as the first projected portion and a connecting portion remaining 513a as the second projected portion, which are projecting from the outer end portion of the printed board 214. Lengths of the connecting portion remainings 514a and 515a in projecting directions thereof are longer than lengths of the connecting portion remainings 511a, 512a and 513a in projecting directions thereof.

The connecting portion remainings of the connecting portions 514 and 515 of connecting portion lengths of 2.0 mm is 1.0 mm from tips thereof to the outer end portions of each of the printed boards. On the other hand, the connecting portion remainings of the connecting portions 511, 512 and 513 of connecting portion lengths of 1.0 mm is 0.5 mm from tips thereof to the outer end portions of each of the printed boards. A difference between the lengths of these connecting portion remainings is 0.5 mm. The connecting portion remaining of longer connecting portion is 1.0 mm, which is the same length as the connecting portion remaining assumed in a case of being divided by hand, therefore it becomes possible to keep assumed specification for the conventional printed board.

In the Embodiment 1, due to the configuration of the printed board, the lengths of the shorter connecting portions 511, 512 and 513 of the collective printed board-to-be-divided 911 are configured to be 1.0 mm, however, as long as the connecting portion can be formed and divided by the board dividing device, it may be configured to be 1.0 mm or less. In addition, the clearance between the dividing blade and the mounted components is configured to be 1.0 mm, however, in light of the configuration of the board dividing device, as long as a distance, with which the dividing blade and the mounted components do not hit each other, can be kept, the length is not limited thereto.

In addition, the connecting portions 514 and 515, of which the lengths of the connecting portions are longer, are configured to be 2.0 mm, however, the lengths also are not limited thereto. The length of the connecting portion can be adjusted depending on the shape and the size of the printed boards to be connected to each other. As long as the length of the connecting portion remaining after being divided, which are divided at the center of the connecting portion, satisfies specification and there is no problem in the connecting strength of the printed board and the jetting up during the flow soldering, the length is not limited. For example, a printed board which are connected only by the longer connecting portion may be included in the collective printed board-to-be-divided.

As described above, according to the Embodiment 1, it becomes possible to keep the strength of the collective printed board.

### EMBODIMENT 2

### Problem in the Conventional Collective Printed Board-to-be-Divided

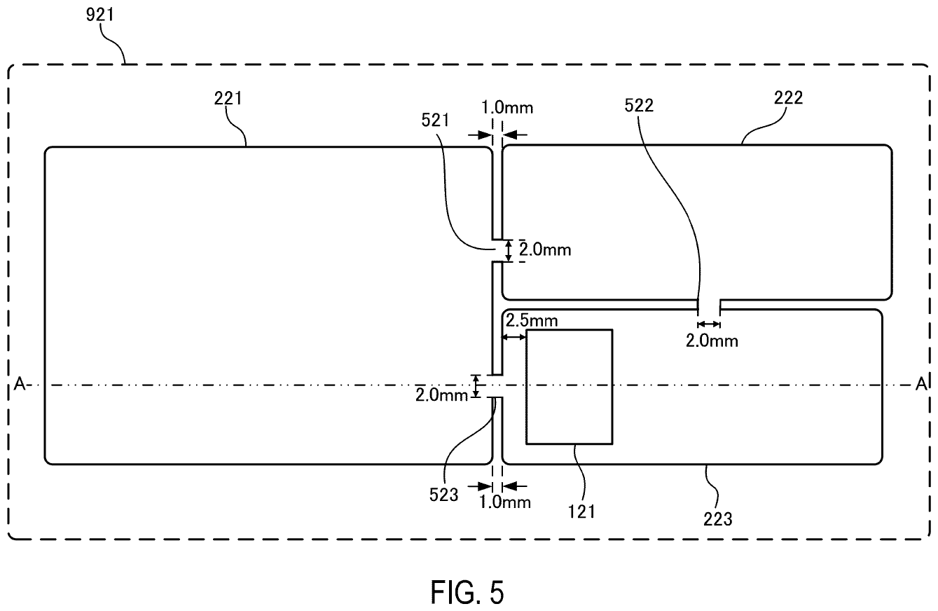

FIG. 5 is a view illustrating a configuration of an example of one sheet of a conventional collective printed board-to-be-divided, in which a plurality of the printed boards are connected by the connecting portions having the same length of 1.0 mm and the same width of 2.0 mm. Three sheets of the printed boards 221, 222 and 223 are connected by the connecting portions 521, 522 and 523 having the length of 1.0 mm, respectively, and the collective printed board-to-be-divided 921 is constituted. On the printed board 223, a connector 121 is mounted at a position of 2.5 mm from an outer end side portion of the printed board 223, to which the connecting portion 523 is connected.

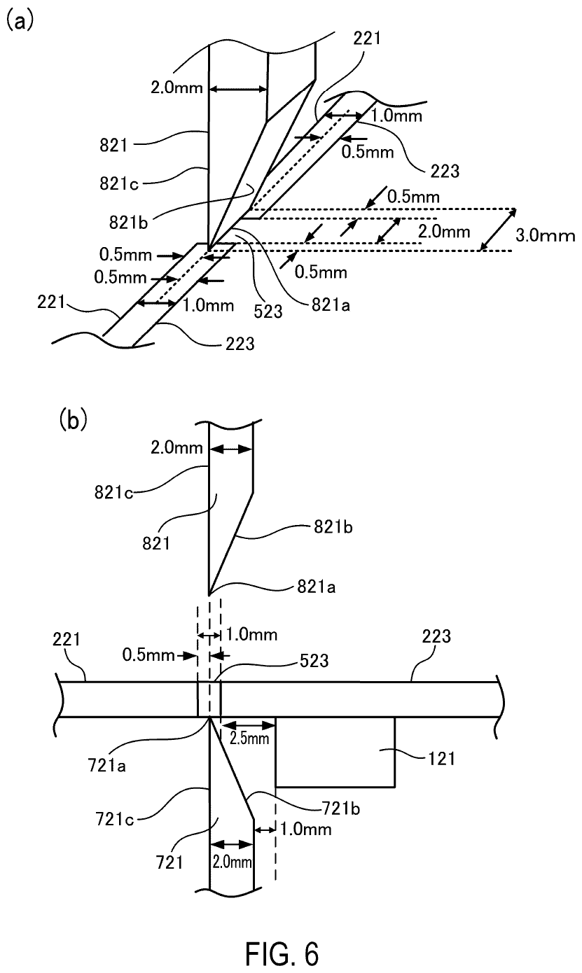

In part (a) of FIG. 6, in a case in which the collective printed board-to-be-divided 921 is divided by the board dividing device 100, a dimensional view of vicinity of the connecting portion 523 upon an upper dividing blade 821 contacting the contacting portion 523 is illustrated. A leading edge 821a of the upper dividing blade 821 is formed by a crossing line between an inclined surface 821b and a vertical surface 821c, and a blade width of the upper dividing blade 821 is 3.0 mm, and a thickness of the blade is 2.0 mm. A position of the leading edge 821a of the upper dividing blade 821 is, with respect to the connecting portion 523, a position, which is 0.5 mm away from an outer end side portion of the printed board 221, and is a position, which is 0.5 mm away from the outer end side portion of the printed board 223. A position of the leading edge 821a is positioned, with respect to the width 2.0 mm of the connecting portion 523, so that a center of the leading edge 821a of the blade width of 3.0 mm overlaps a center of the width of the connecting portion 523, and the blade contacts a center of the connecting portion length of 1.0 mm. In this manner, the connecting portion 523 is sandwiched between the upper dividing blade 821 and the lower dividing blade 721 (see part (b) of FIG. 6) and cut. A direction of the upper dividing blade 821 is a direction, in which the inclined surface 821b faces the connector 121, which is not shown in part (a) of FIG. 6.

In part (b) of FIG. 6, of an A-A cross-section of the collective printed board-to-be-divided 921 shown in FIG. 5, a cross-sectional view, in which the vicinity of the connecting portion 523 is enlarged, is illustrated and the upper dividing blade 821 and the lower dividing blade 721 before dividing are illustrated together. The lower dividing blade 721 includes a leading edge 721a, an inclined surface 721b and a vertical surface 721c. The inclined surface 821b of the upper dividing blade 821 and the inclined surface 721b of the lower dividing blade 721 are disposed, as shown in part (b) of FIG. 6, so as to face directions in which the inclined surfaces 821b and 721b face the connector 121. In this case, between the lower dividing blade 721 and the connector 121, so as not to contact each other upon division of the printed board, a clearance of 1.0 mm or more is secured. Therefore, the connector 121 can only be disposed in a position, which is distanced 2.5 mm or more from the outer end side portion of the printed board 223, to which the connecting portion 523 is connected. In other words, there is a problem that the connector 121 cannot be disposed so as an outer end portion thereof to overlap the outer end portion of the printed board 223 (right on the outer end portion of the printed board).

In a case in which the printed boards are connected by the conventional connecting portions having the common length of 1 mm, as a way for disposing a component to be mounted such as the connector 121 on the outer end portion of the printed board 223, there is a way to remove (not to form) the connecting portion 523. However, in this case, the printed board 223 is connected only by the connecting portion 522, therefore, connecting strength of the collective printed board-to-be-divided 921 may be reduced. In addition, as another way for disposing a component to be mounted such as the connector 121 on the outer end portion of the printed board 223, a way in which only the connecting portion 523 is divided separately by hand instead of using the board dividing device can be considered, however, there is a problem that man-hours for dividing the printed board increase.

### Collective Printed Board-to-be-Divided in an Embodiment 2

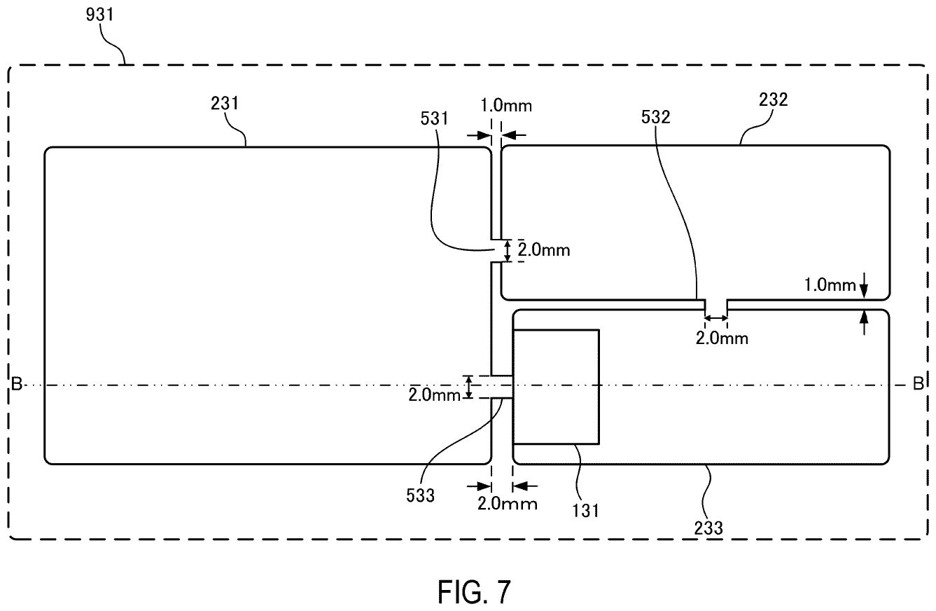

FIG. 7 is a view illustrating a configuration of a collective printed board-to-be-divided 931 in an Embodiment 2, in which a plurality of the printed boards are connected by connecting portions. Three sheets of printed boards 231, 232 and 233 are connected by connecting portions 531, 532 and 533, and the collective printed board-to-be-divided 931 is constituted. Lengths of the connecting portion 531 and the connecting portion 532 are 1.0 mm, and a length of the connecting portion 533 is 2.0 mm, and a connector 131 is mounted on an outer end portion of a printed board 233, which is adjacent to the connecting portion 533. Widths of the connecting portions 531, 532 and 533 are all 2.0 mm.

### Contacting Manner of an Upper Dividing Blade

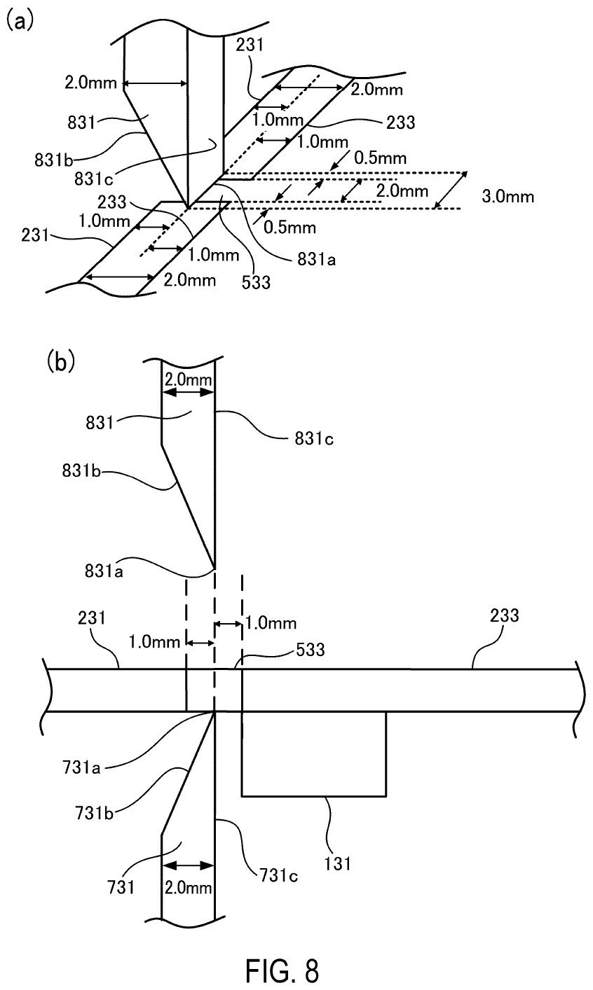

In part (a) of FIG. 8, in a case in which the collective printed board-to-be-divided 931 is divided by the board dividing device 100, a dimensional view of vicinity of the connecting portion 533 upon an upper dividing blade 831 contacting the contacting portion 533 is illustrated. In addition, as shown in part (b) of FIG. 8, the connector 131 as a component is mounted to a lower surface of the printed board 233.

Upon dividing the printed board, a position of a leading edge 831a of the upper dividing blade 831 is, with respect to the connecting portion 533, is a position, which is 1.0 mm away from an outer end side portion of the printed board 231, and a position, which is 1.0 mm away from an outer end side portion of the printed board 233. A position of the leading edge 831a is positioned, with respect to the width 2.0 mm of the connecting portion 533, so that a center of a blade width of 3.0 mm overlaps a center of the width of the connecting portion, and the blade contacts a center of the connecting portion length of 2.0 mm. The connecting portion 533 is sandwiched between the upper dividing blade 831 and a lower dividing blade 731 (see part (b) of FIG. 8) and cut. A direction of the upper dividing blade 831 is an opposite direction, in which an inclined surface 831b does not face the connector 131, which is not shown. In other words, the direction of the upper dividing blade 831 is in a direction in which a vertical surface 831c faces the connector 131.

In part (b) of FIG. 8, of a B-B cross-section of the collective printed board-to-be-divided 931 shown in FIG. 7, a cross-sectional view, in which the vicinity of the connecting portion 533 is enlarged, is illustrated, and the upper dividing blade 831 and the lower dividing blade 731 are illustrated together. The leading edge 831a of the blade of the upper dividing blade 831 and a leading edge 731a of the blade of the lower dividing blade 731 are disposed, as shown in part (b) of FIG. 8, so that the inclined surface 831b and an inclined surface 731b of each blade face opposite to the direction facing the connector 131. In other words, the direction of the upper dividing blade 831 is the direction in which the vertical surface 831c faces the connector 131, and a direction of the lower dividing blade 731 is a direction in which a vertical surface 731c faces the connector 131.

In this case, between the lower dividing blade 731 and the connector 131, a clearance of 1.0 mm is taken so as not to contact each other upon dividing, therefore even if the connecting portion 533 is connected, it becomes possible for the connector 131 to be mounted on the outer end portion of the printed board 233. In cases of the connecting portions 531 and 532 as well, similarly, corresponding upper and lower dividing blades contact centers of the connecting portions, and at centers of lengths of the connecting portions, the connection portions are cut. In addition, upon dividing into the printed boards, mounted components on each printed board, which are not shown in the figure, are mounted on the printed board so as to take a clearance of 1.0 mm or more to the upper and lower dividing blades.

Incidentally, the connector 131 may be mounted on an upper surface of the printed board 233. In this case, the vertical surface 831c as the first vertical surface of the upper dividing blade 831 as the first upper dividing blade may be disposed so as to face the connector 131. In addition, the connector 131 may be mounted on an upper surface or to a lower surface of the printed board 231. In either case, the vertical surface 831c of the upper dividing blade 831 or the vertical surface 731c as the second vertical surface of the lower dividing blade 731 as the first lower dividing blade may be disposed so as to face the connector 131.

Furthermore, in a case as FIG. 5, i.e., in a case in which the length of the connecting portion 523 is 1 mm as well, by disposing so that the vertical surface of the blade faces the component, it becomes possible to mount the component on the end portion of the printed board. In other words, in a case in which the connector 121 is mounted to the lower surface of the printed board 223, the lower dividing blade 721 as the first lower dividing blade may be disposed so that the vertical surface 721c as the second vertical surface face the connector 121. In addition, the connector 121 may be disposed on the upper surface of the printed board 223. In this case, the vertical surface 821c as the first vertical surface of the upper dividing blade 821 as the first upper dividing blade may be disposed so as to face the connector 121. Furthermore, the connector 121 may be mounted on the upper surface or to the lower surface of the printed board 221. In either case, the vertical surface 821c of the upper dividing blade 821 or the vertical surface 721c as the second vertical surface of the lower dividing blade 721 as the first lower dividing blade may be disposed so as to face the connector 121. In other words, in a case in which the connector 121 is mounted on the upper surface or the lower surface of the printed board 221, which is adjacent to the connecting portion 523, the upper dividing blade 821 and the lower dividing blade 721 may be disposed in the direction as shown in part (b) of FIG. 6.

### Printed Board After Being Divided

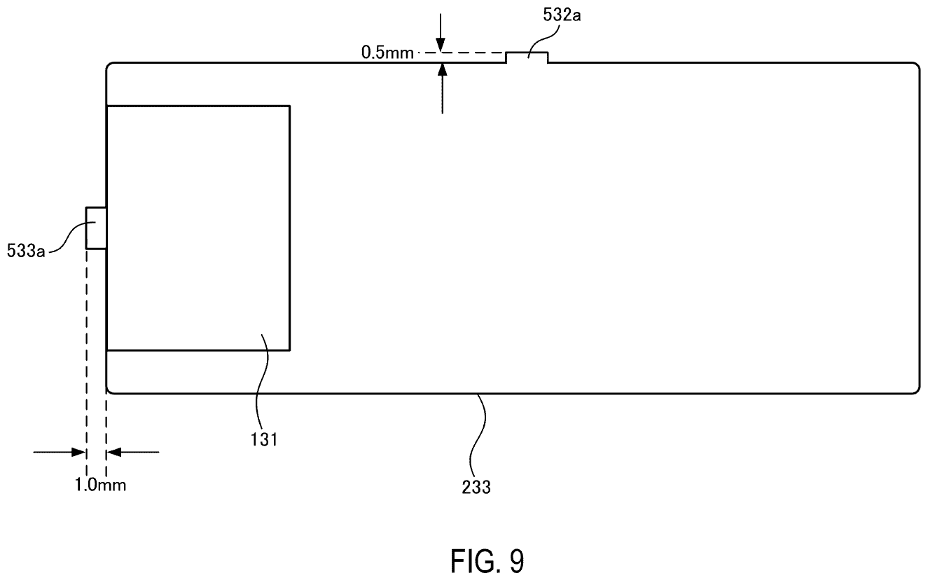

FIG. 9 shows the printed board 233 after being divided. On the end portion, in which a connecting portion remaining 533a as the first projected portion projects, the connector 131, which is a component, is mounted. A length of the connecting portion remaining 533a in a projecting direction is 1.0 mm or more, and a length of a connecting portion remaining 533b as the second projected portion in a projecting direction is 0.5 mm or less. In other words, a difference between the length in the direction in which the connecting portion remaining 533a projects and the length in the direction in which the connecting portion remaining 533b projects is 0.5 mm or more.

The connecting portion remaining 533a of the connecting portion 533 of the connecting portion length of 2.0 mm is 1.0 mm from a tip to the outer end portion of each printed board 233. In addition, the connecting portion remaining 532a of the connecting portion 532 of the connecting portion length of 1.0 mm is 0.5 mm from a tip to the outer end portion of each printed board 233. Therefore, the difference between the lengths of two connecting portion remainings 533a and 532a is 0.5 mm.

In the Embodiment 2, due to the configuration of the printed board, the length of the shorter connecting portion of the collective printed board-to-divided is configured to be 1.0 mm, however, as long as the connecting portion can be formed and divided by the board dividing device, it may be configured to be 1.0 mm or less. In addition, the clearance between the dividing blade and the mounted components is configured to be 1.0 mm, however, as long as a distance, in which the dividing blade and the mounted components do not hit each other, is taken, the length is not limited thereto.

In addition, the longer connecting portion is configured to be 2.0 mm, however, only the clearance between the connector and the lower dividing blade has to be taken upon dividing the printed board, and the length can be adjusted depending on the shape and the size of the printed board to be connected. As long as the length of the connecting portion remaining after being divided satisfies specification and there is no problem in the connecting strength of the printed board and the jetting up during the flow soldering, the connecting portion length is not limited.

In addition, in the Embodiment 2, the longer connecting portion, which is connected to a predetermined printed board, is only one point, however, there may be two or more. As long as the clearance, with which the upper and lower dividing blades and the components to be mounted on the printed board do not contact each other, is taken, the connectors may be mounted at positions adjacent to the longer connecting portions, respectively. By this, it becomes possible to flexibly connect a point, which the conventional connecting portion having the common length of 1.0 mm cannot connect, and even in a case in which a plurality of the connectors need to be mounted on the outer end portion of the printed board as well, freedom in disposing the connecting portion for keeping the connecting strength is increased. As a component adjacent to the longer connecting portion, the connector has been described as an example, however, all components to be mounted on a board are in the scope and it is not limited to the connector.

As described above, according to the Embodiment 2, it becomes possible to keep the strength of the collective printed board.

### EMBODIMENT 3

### Collective Printed Board-to-be-Divided in an Embodiment 3

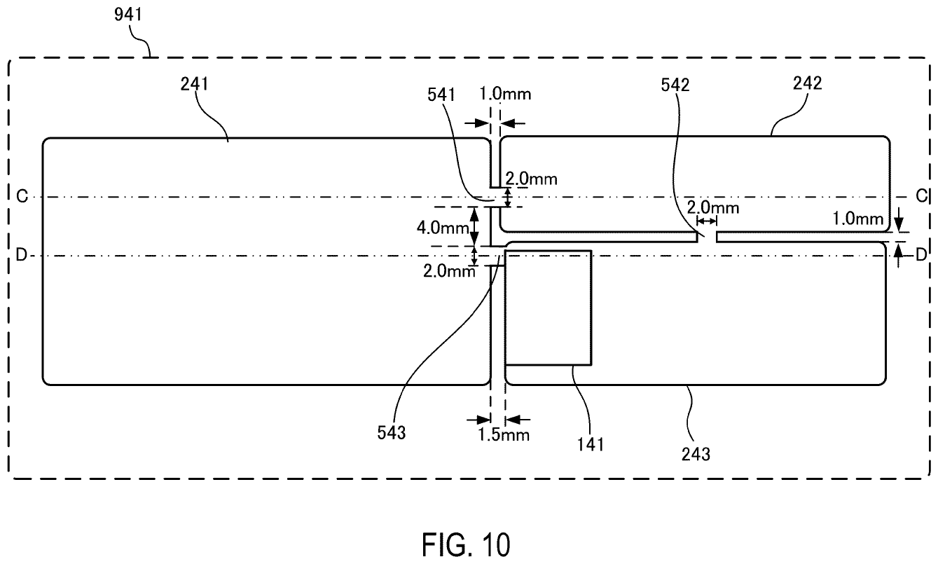

FIG. 10 is a view illustrating a configuration of a collective printed board-to-be-divided 941, in which a plurality of printed boards are connected by connecting portions in an Embodiment 3. Three sheets of the printed boards 241, 242 and 243 are connected by connecting portions 541, 542 and 543, and the collective printed board-to-be-divided 941 is constituted. Lengths of the connecting portion 541 and the connecting portion 542 are 1.0 mm, a length of the connecting portion 543 is 1.5 mm, and between the connecting portion 541 and the connecting portion 543, a distance of 4.0 mm is taken, and widths thereof are 2.0 mm, respectively. As such, a longer connecting portion only has to have a length of 1.5 mm or more. A connector 141 is mounted on an outer end portion of the printed board 243, which is adjacent to the connecting portion 543.

### Contacting Manner of an Upper Dividing Blade

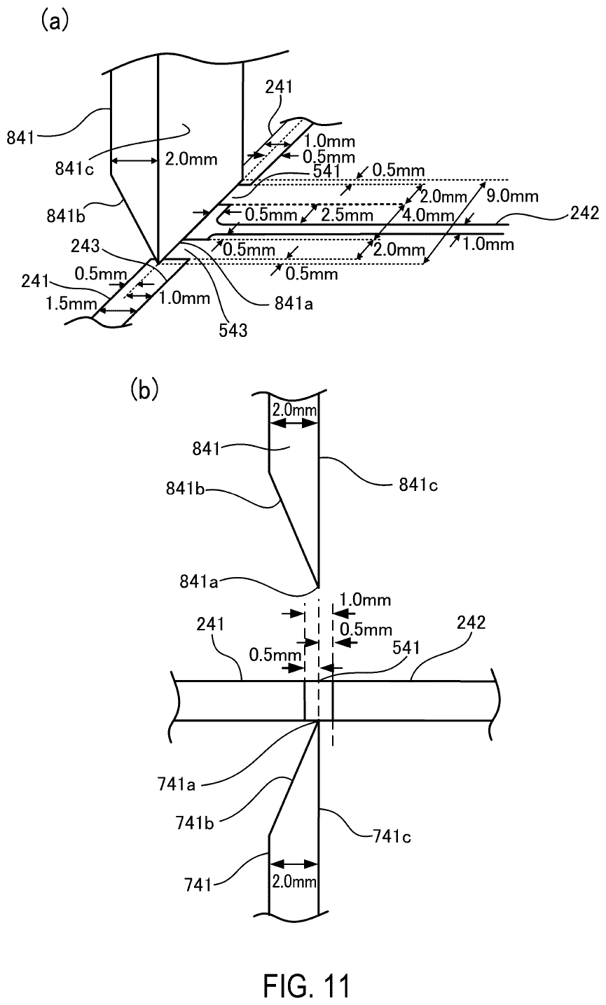

In part (a) of FIG. 11, in a case in which the collective printed board-to-be-divided 941 is divided by the board dividing device 100, a dimensional view of vicinity of the connecting portion upon an upper dividing blade 841 contacting the contacting portions 541 and 543 is illustrated. A leading edge 841a of the upper dividing blade 841 is formed by a crossing line between an inclined surface 841b and a vertical surface 841c thereof, and a blade width is 9.0 mm and a thickness of the blade is 2.0 mm. A leading edge 741a of a lower dividing blade 741 is formed by a crossing line between an inclined surface 741b and a vertical surface 741c thereof, and a blade width is 9.0 mm and a thickness of the blade is 2.0 mm (see part (b) of FIG. 11).

A position of the leading edge 841a of the upper dividing blade 841 is, with respect to the connecting portion 541, a position, which is 0.5 mm away from an outer end side portion of the printed board 241, and a position, which is 0.5 mm away from an outer end side portion of the printed board 242. The leading edge 841a of the upper dividing blade 841 contacts a center of a connecting portion length 1.0 mm of the connecting portion 541. The leading edge 841a is, with respect to the connecting portion 543, in a position, which is 0.5 mm away from the outer end side portion of the printed board 241, and in a position, which is 1.0 mm away from an outer end portion of the printed board 243. The upper dividing blade 841 and the lower dividing blade 741, in a length direction of the connecting portion 543 as the first connecting portion, cut between a center of the connecting portion 543 and the outer end portion of the printed board 241, and in a length direction of the connecting portion 541 as the second connecting portion, cut the center of the connecting portion 541.

The leading edge 841a of the upper dividing blade 841 is, with respect to a widthwise direction, in a position in which a center of the dividing blade width of 9.0 mm overlaps a center of the connecting portion 541 and the connecting portion 543, and the connecting portion 543 is sandwiched between the upper dividing blade 841 and the lower dividing blade 741 and cut. Directions of the upper dividing blade 841 and the lower dividing blade 741 are in opposite directions, in which each of the inclined surfaces 841b and 741b does not face a connector 141, which is not shown. In other words, the direction of the upper dividing blade 841 and the lower dividing blade 741 is a direction in which each of the vertical surfaces 841c and 741c face the connector 141, which is not shown.

In part (b) of FIG. 11, of a C-C cross-section of the collective printed board-to-be-divided 931 shown in FIG. 10, a cross-sectional view, in which the vicinity of the connecting portion 541 is enlarged, is illustrated, and the upper dividing blade 841 and the lower dividing blade 741 are illustrated together. The leading edge 841a of the blade of the upper dividing blade 841 and the leading edge 741a of the blade of the lower dividing blade 741 are disposed, as shown in part (b) of FIG. 11, so that the inclined surfaces 841b and 741b of each blade face an opposite to a direction facing the printed board 242.

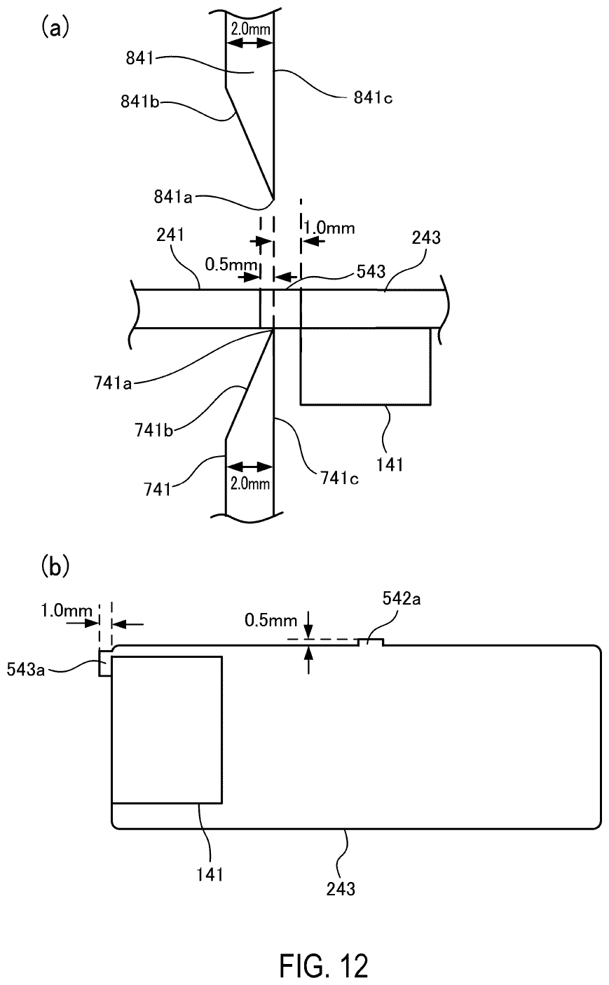

In part (a) of FIG. 12, of a D-D cross-section of the collective printed board-to-be-divided 941 shown in FIG. 10, a cross-sectional view, in which the vicinity of the connecting portion 543 is enlarged, is illustrated, and the upper dividing blade 841 and the lower dividing blade 741 are illustrated together. The leading edge 841a of the blade of the upper dividing blade 841 and the leading edge 741a of the blade of the lower dividing blade 741 are disposed, as shown in part (a) of FIG. 12, so that the inclined surfaces 841b and 741b of each blade face an opposite to a direction facing the connector 141. In this case, between the lower dividing blade 741 and the connector 141, a clearance of 1.0 mm so as not to contact each other upon dividing is taken, therefore even if the connecting portion 543 is connected, it becomes possible for the connector 141 to be mounted on the outer end portion of the printed board 243. Incidentally, in a case of the connecting portion 542, similar to the Embodiment 2, corresponding upper and lower dividing blades contact a center of the connecting portion, and at a center of the length of the connecting portion, the connection portion is cut. In addition, upon dividing into the printed boards, mounted components on each printed board, which are not shown in the figure, are mounted on the printed board so as to take a clearance of 1.0 mm or more to the upper and lower dividing blades.

### Printed Board After Being Divided

Part (b) of FIG. 12 shows the printed board 243 after being divided. A connecting portion remaining 543a of the connecting portion 543 of the connecting portion length of 1.5 mm is 1.0 mm from a tip thereof to the outer end portion of each printed board 243. On the other hand, a connecting portion remaining 542a of the connecting portion 542 of the connecting portion length of 1.0 mm is 0.5 mm from a tip thereof to the outer end portion of each printed board. A difference between the lengths of each connecting portion remaining is 0.5 mm.

In the Embodiment 3, due to the configuration of the printed board, the length of the shorter connecting portion of the collective printed board-to-divided is configured to be 1.0 mm, however, as long as the connecting portion can be divided by the board dividing device, the length may be configured to be 1.0 mm or less. In addition, the clearance between the dividing blade and the mounted components is configured to be 1.0 mm, however, in light of the board dividing device, as long as a distance, with which the dividing blade and the mounted components do not hit, is taken, the distance of the clearance is not limited thereto.

In addition, the length of the longer connecting portion is configured to be 1.5 mm, however, as long as the clearance between the connector and the lower dividing blade is taken upon dividing the collective printed board-to-be-divided, the length thereof can be adjusted depending on the shape and the size of the printed boards to be connected. As long as the length of the connecting portion remaining after the collective printed board-to-be-divided is divided satisfies specification and there is no problem in the connecting strength of the printed board before the collective printed board-to-be-divided is divided and the jetting up during the flow soldering, the length of the connecting portion is not limited. Furthermore, the connector, which is adjacent to the longer connecting portion, has been described as an example of the mounted component, however, all of components to be mounted on a board are in the scope.

As described above, according to the Embodiment 3, it becomes possible to keep the strength of the collective printed board.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-024230 filed on Feb. 21, 2024, which is hereby incorporated by reference herein in its entirety.

What is claimed is:

1. A printed board manufacturing method for manufacturing a plurality of printed boards by cutting connecting portions of a collective printed board in which the plurality of printed boards are connected by the connecting portions and are disposed, wherein the collective printed board comprising:
a first printed board;
a second printed board;
a third printed board;
a first connecting portion connecting the first printed board and the second printed board; and
a second connecting portion connecting the first printed board and the third printed board,
wherein a length of the first connecting portion in a direction where the first printed board and the second printed board are connected is longer than a length of the second connecting portion in a direction where the first printed board and the third printed board are connected, and
wherein the first printed board, the second printed board and the third printed board are manufactured from the collective printed board by the first connecting portion being cut with the second connecting portion.

2. The printed board manufacturing method according to claim 1,
wherein the first connecting portion and the second connecting portion are divided by a dividing device,
wherein in a state in which the collective printed board is mounted on the dividing device, the dividing device includes a lower dividing blade provided below the collective printed board in a vertical direction and an upper dividing blade provided above the collective printed board so as to be paired with the lower dividing blade,
wherein the upper dividing blade and the lower dividing blade include a first upper dividing blade and a first lower dividing blade which cut the first connecting portion and a second upper dividing blade and a second lower dividing blade which cut the second connecting portion,
wherein the first upper dividing blade includes a first vertical surface parallel to the vertical direction, a first inclined surface inclined to the vertical direction and a first leading edge portion formed of a crossing line between the first vertical surface and the first inclined surface,
wherein the first lower dividing blade includes a second vertical surface parallel to the vertical direction, a second inclined surface inclined to the vertical direction and a second leading edge portion formed of a crossing line between the second vertical surface and the second inclined surface,
wherein the second upper dividing blade includes a third vertical surface parallel to the vertical direction, a third inclined surface inclined to the vertical direction and a third leading edge portion formed of a crossing line between the third vertical surface and the third inclined surface,
wherein the second lower dividing blade includes a fourth vertical surface parallel to the vertical direction, a fourth inclined surface inclined to the vertical direction and a fourth leading edge portion formed of a crossing line between the fourth vertical surface and the fourth inclined surface,
wherein the collective printed board is mounted on the dividing device so that the first connecting portion is positioned above the first lower dividing blade and the second connecting portion is positioned above the second lower dividing blade, and
wherein the first upper dividing blade contacts the first connecting portion from above the first connecting portion, comes into slide contact with the first lower dividing blade through the first connecting portion and cuts the first connecting portion, and
wherein the second upper dividing blade contacts the second connecting portion from above the second connecting portion, comes into slide contact with the second lower dividing blade through the second connecting portion and cuts the second connecting portion.

3. The printed board manufacturing method according to claim 2,
wherein the first upper dividing blade and the first lower dividing blade cut a center of the first connecting portion in a length direction of the first connecting portion, and
wherein the second upper dividing blade and the second lower dividing blade cut a center of the second connecting portion in a length direction of the second connecting portion.

4. The printed board manufacturing method according to claim 2,
wherein the first printed board or the second printed board includes a component mounted on an end portion to which the first connecting portion is connected,
wherein in a case in which the component is mounted on an upper surface of the first printed board or the second printed board, the first vertical surface of the first upper dividing blade is disposed so as to be opposed to the component, and
wherein in a case in which the component is mounted on a lower surface of the first printed board or the second printed board, the second vertical surface of the first lower dividing blade is disposed so as to be opposed to the component.

5. The printed board manufacturing method according to claim 2,
wherein the first printed board or the third printed board includes a component mounted on an end portion to which the second connecting portion is connected,
wherein in a case in which the component is mounted on an upper surface of the first printed board or the third printed board, the third vertical surface of the second upper dividing blade is disposed so as to be opposed to the component, and
wherein in a case in which the component is mounted on a lower surface of the first printed board or the third printed board, the fourth vertical surface of the second lower dividing blade is disposed so as to be opposed to the component.

6. A printed board manufacturing method for manufacturing a plurality of printed boards by cutting a connecting portion of a collective printed board in which the plurality of printed boards are connected by the connecting portion and are disposed, wherein the collective printed board comprising:
a first printed board;
a second printed board; and
a connecting portion connecting the first printed board and the second printed board,
wherein the first printed board or the second printed board includes a component mounted on an end portion to which the connecting portion is connected,
wherein the connecting portion is divided by a dividing device,
wherein in a state in which the collective printed board is mounted on the dividing device, the dividing device includes a lower dividing blade provided below the collective printed board in a vertical direction and an upper dividing blade provided above the collective printed board so as to be paired with the lower dividing blade,
wherein the upper dividing blade includes a first vertical surface parallel to the vertical direction, a first inclined surface inclined to the vertical direction and a first leading edge portion formed of a crossing line between the first vertical surface and the first inclined surface,
wherein the lower dividing blade includes a second vertical surface parallel to the vertical direction, a second inclined surface inclined to the vertical direction and a second leading edge portion formed of a crossing line between the second vertical surface and the second inclined surface,
wherein the collective printed board is mounted on the dividing device so that the connecting portion is positioned above the lower dividing blade,
wherein in a case in which the component is mounted on an upper surface of the first printed board or the second printed board, the first vertical surface of the upper dividing blade is disposed so as to be opposed to the component,
wherein in a case in which the component is mounted on a lower surface of the first printed board or the second printed board, the second vertical surface of the lower dividing blade is disposed so as to be opposed to the component, and
wherein the upper dividing blade contacts the connecting portion from above the connecting portion, comes into slide contact with the lower dividing blade through the connecting portion and cuts the connecting portion, and thereby the first printed board and the second printed board are manufactured from the collective printed board.

7. A printed board manufacturing method according to claim 6, wherein when the connecting portion is a first connecting portion, the collective printed board includes a third printed board and a second connecting portion connecting the first printed board and the third printed board, and
wherein a length of the first connecting portion in a direction where first printed board and the second printed board are connected is longer than a length of the second connecting portion in a direction where first printed board and the third printed board are connected.

8. A printed board manufacturing method according to claim 7, wherein when the upper dividing blade is a first upper dividing blade and the lower dividing blade is a first lower dividing blade, the second connecting portion is divided by the dividing device with the first connecting portion and the dividing device includes a second upper dividing blade and a second lower dividing blade which divide the second connecting portion,
wherein the second upper dividing blade includes a third vertical surface parallel to the vertical direction, a third inclined surface inclined to the vertical direction and a third leading edge portion formed of a crossing line between the third vertical surface and the third inclined surface,
wherein the second lower dividing blade includes a fourth vertical surface parallel to the vertical direction, a fourth inclined surface inclined to the vertical direction and a fourth leading edge portion formed of a crossing line between the fourth vertical surface and the fourth inclined surface,
wherein the collective printed board is mounted on the dividing device so that the second connecting portion is positioned above the second lower dividing blade, and
wherein the second upper dividing blade contacts the second connecting portion from above the second connecting portion, comes into slide contact with the second lower dividing blade through the second connecting portion and cuts the second connecting portion.

9. A printed board manufacturing method according to claim 6, wherein when the connecting portion is a first connecting portion, the collective printed board includes a third printed board and a second connecting portion connecting the first printed board and the third printed board,
wherein a length of the first connecting portion in a direction where first printed board and the second printed board are connected is longer than a length of the second connecting portion in a direction where the first printed board and the third printed board are connected,
wherein the collective printed board is mounted on the dividing device so that the second connecting portion is positioned above the lower dividing blade with the first connecting portion, and
wherein the upper dividing blade contacts the first connecting portion and the second connecting portion from above the second connecting portion, comes into slide contact with the lower dividing blade through the first connecting portion and the second connecting portion and cuts the second connecting portion and the first connecting portion.

10. The printed board manufacturing method according to claim 9,
wherein the upper dividing blade and the lower dividing blade cut between a center of the first connecting portion and an outer end portion of the first printed board in a length direction of the first connecting portion, and cut a center of the second connecting portion in a length direction of the second connecting portion.

11. The printed board manufacturing method according to claim 1,
wherein a length of the first connecting portion is 1.5 mm or more, and
wherein a length of the second connecting portion is 1.0 mm or less.

12. The printed board manufacturing method according to claim 1, wherein a difference between a length of the first connecting portion and a length of the second connecting portion is 0.5 mm or more.

13. A printed board on which a component is to be mounted, the printed board comprising:
a first projected portion and a second projected portion projected from an outer end portion of the printed board,
wherein a length of the first projected portion in a direction where the first projected portion is projected is longer than a length of the second projected portion in a direction where the second projected portion is projected.

14. The printed board according to claim 13, wherein the component is mounted on an end portion where the first projected portion is projected.

15. The printed board according to claim 13,
wherein a length of the first projected portion in a direction where the first projected portion is projected is 1.0 mm or more, and
wherein a length of the second projected portion in a direction where the second projected portion is projected is 0.5 mm or less.

16. The printed board according to claim 13, wherein a difference between a length of the first projected portion in a direction where the first projected portion is projected and a length of the second projected portion in a direction where the second projected portion is projected is 0.5 mm or more.
